(19) United States
(12) Patent Application Publication
(10) Pub. No.: US 2025/0287814 A1
(43) Pub. Date: Sep. 11, 2025

(54) DISPLAY DEVICE AND METHOD OF MANUFACTURING THE SAME

(71) Applicant: Samsung Display Co., LTD., Yongin-si (KR)

(72) Inventors: Ohjune KWON, Yongin-si (KR); Heejun YANG, Yongin-si (KR); Jeongseok LEE, Yongin-si (KR)

(21) Appl. No.: 18/952,604

(22) Filed: Nov. 19, 2024

(30) Foreign Application Priority Data
Mar. 5, 2024 (KR) 10-2024-0031525

(51) Int. Cl. H10K 59/80; H10K 59/12

(52) U.S. Cl. CPC H10K 59/873; H10K 59/1201

(57) ABSTRACT

A display device includes a display panel including one surface, on which a screen is defined, and an opposing surface located opposite to the one surface, a first bonding target located in a first area of the opposing surface, and a first resin layer located between the first bonding target and the opposing surface and covering at least a portion of a lateral surface of the first bonding target.

This application claims priority to Korean Patent Application No. 10-2024-0031525, filed on Mar. 5, 2024, and all the benefits accruing therefrom under 35 U.S.C. § 119, the content of which in its entirety is herein incorporated by reference.

### BACKGROUND

### 1. Field

One or more embodiments relate to a display device and a method of manufacturing the display device, and more particularly, to a display device and a method of manufacturing the display device to prevent damage due to pressure applied when a certain component is attached to a display panel.

### 2. Description of the Related Art

A display device is a device that receives information about an image and displays the image. The display device is sometimes used as a display unit for a small-sized product such as a mobile phone, and is also used as a display unit for a large-sized product such as a television.

The display device typically includes a plurality of pixels that receive electrical signals and emit light to display an image to the outside. Each pixel may include a light emitting device, and for example, in a case where the display device is an organic light emitting display device, each pixel includes an organic light emitting diode (OLED) as a light emitting device. Generally, in an organic light emitting display device, a thin film transistor and an OLED are formed on a substrate, and the OLED operates by self-emitting light.

The display device may include a display panel, and various components may be attached to a rear surface of the display panel. Generally, an adhesive layer is used to attach various components, and a pressurizing process is performed to attach the components by using the adhesive layer.

### SUMMARY

One or more embodiments include a display device and a method of manufacturing the display device to prevent damage due to pressure applied when a certain component is attached to a display panel. However, this is illustrative and does not limit the scope of the disclosure.

Additional aspects will be set forth in part in the description which follows and, in part, will be apparent from the description, or may be learned by practice of the presented embodiments of the disclosure.

According to one or more embodiments, a display device includes a display panel including one surface, on which a screen is defined, and an opposing surface located opposite to the one surface, a first bonding target located in a first area of the opposing surface, and a first resin layer located between the first bonding target and the opposing surface and covering at least a portion of a lateral surface of the first bonding target.

In an embodiment, the display device may further include a first upper resin layer disposed on the first resin layer and covering at least a portion of an upper surface of the first bonding target.

In an embodiment, when viewed in a direction perpendicular to the opposing surface, an area of the first resin layer may be greater than an area of the first bonding target.

In an embodiment, the display device may further include a cushion layer located between the first resin layer and the opposing surface.

In an embodiment, the first resin layer may include one of an optical curing resin and a thermo-curing resin.

In an embodiment, the first resin layer may further include a metallic material mixed with the one of the optical curing resin and the thermo-curing resin.

In an embodiment, the display device may further include a second bonding target located in a second area of the opposing surface, which is located around the first area, and a second resin layer located between the second bonding target and the opposing surface and covering at least a portion of a lateral surface of the second bonding target.

In an embodiment, the first resin layer in the first area may include one of an optical curing resin and a thermo-curing resin, and the second resin layer in the second area may include the other of the optical curing resin and the thermo-curing resin.

In an embodiment, the display device may further include an integrated circuit film which is connected to the display panel and on which a driving integrated circuit is mounted, and the first bonding target may include a printed circuit board connected to the integrated circuit film.

In an embodiment, the first resin layer may cover at least a portion of an upper surface of the first bonding target.

According to one or more embodiments, a method of manufacturing a display device includes preparing a display panel including one surface, on which a screen is defined, and an opposing surface located opposite to the one surface, forming a first resin layer on the opposing surface by applying resin to a first area of the opposing surface, locating a first bonding target on the first resin layer, after the locating the first bonding target, waiting for a certain time, and curing the first resin layer.

In an embodiment, the method may further include after the curing the first resin layer, forming a first upper resin layer by further applying the resin to the first resin layer and the first bonding target, and curing the first upper resin layer.

In an embodiment, the method may further include forming a cushion layer on the opposing surface, and the forming the first resin layer may include applying the resin to the opposing surface and the cushion layer.

In an embodiment, when viewed in a direction perpendicular to the opposing surface, an area of the first resin layer may be greater than an area of the first bonding target.

In an embodiment, the first resin layer may include an optical curing resin or a thermo-curing resin.

In an embodiment, the first resin layer may further include a metallic material mixed with the optical curing resin or the thermo-curing resin.

In an embodiment, the method may further include forming a second resin layer by applying the resin to a second area of the opposing surface, which is located around the first area, and locating a second bonding target on the second resin layer.

In an embodiment, the method may further include, after the locating the second bonding target, waiting for a certain time, and curing the second upper resin layer.

In an embodiment, the first resin layer in the first area may include one of an optical curing resin and a thermo-curing resin, and the second resin layer in the second area may include the other of the optical curing resin and the thermo-curing resin.

In an embodiment, when viewed in a direction perpendicular to the opposing surface of the display panel, an area of the first resin layer is less than an area of the cushion layer.

### BRIEF DESCRIPTION OF THE DRAWINGS

The above and other features of certain embodiments of the disclosure will be more apparent from the following description taken in conjunction with the accompanying drawings, in which:

FIG. 1 is a schematic perspective view showing a display panel of a display device according to an embodiment;

FIG. 2 is a schematic diagram showing another surface (or rear surface) of the display panel of FIG. 1;

FIG. 3 is a cross-sectional view showing an example of a cross-section of the display panel taken along line I-I′ of FIG. 2;

FIG. 4 is a cross-sectional view showing an example of a cross-section of the display panel taken along line I-I′ of FIG. 2;

FIG. 5 is a cross-sectional view showing an example of a cross-section of the display panel taken along line I-I′ of FIG. 2;

FIG. 6 is a cross-sectional view showing an example of a cross-section of the display panel taken along line I-I′ of FIG. 2;

FIG. 7 is a cross-sectional view showing an example of a cross-section of the display panel taken along line I-I′ of FIG. 2;

FIG. 8 is a cross-sectional view showing an example of a cross-section of the display panel taken along line I-I′ of FIG. 2;

FIG. 9 is a cross-sectional view showing an example of a cross-section of the display panel taken along line I-I′ of FIG. 2;

FIG. 10 is a schematic diagram showing another example of another surface (or rear surface) of the display panel of FIG. 1;

FIGS. 11 to 13 are diagrams showing examples of a cross-section of the display panel taken along line II-II′ of FIG. 10;

FIG. 14 is a schematic flowchart showing a method of manufacturing a display device according to an embodiment;

FIGS. 15 to 18 are diagrams showing the display panel manufactured according to the flowchart of FIG. 14 in order;

FIG. 19 is a schematic flowchart showing a method of manufacturing a display device according to an embodiment;

FIG. 20 is a diagram showing a display panel on which a first upper resin layer of FIG. 19 is formed;

FIG. 21 is a schematic equivalent circuit diagram showing an embodiment of a pixel of the display device of FIG. 1; and

FIG. 22 is a schematic cross-sectional view showing a portion of the display device of FIG. 1.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

As the disclosure allows for various changes and numerous embodiments, particular embodiments will be illustrated in the drawings and described in detail in the written description. The accompanying drawings for illustrating embodiments are referred to gain a sufficient understanding of embodiments, the merits thereof, and the objectives accomplished by the implementation of the disclosure. However, the disclosure is not limited to the embodiments disclosed below, but may be implemented in various different forms.

Hereinafter, the disclosure will be described in detail by explaining the embodiments with reference to the attached drawings, the same reference numerals in the drawings denote like elements, and a repeated explanation thereof will not be given.

It will be understood that when an element is referred to as being “on” another element, it can be directly on the other element or intervening elements may be present therebetween. In contrast, when an element is referred to as being “directly on” another element, there are no intervening elements present. In the following embodiments, when an element such as a layer, a film, a region, and a board is referred to as being “below” another element, the element may be “directly below” another element or intervening elements.

For convenience of explanation, the components may be exaggerated or reduced in the diagrams. For example, sizes and thicknesses of the elements shown in the drawings are for the purpose of descriptive convenience, and thus the disclosure is not necessarily limited thereto. That is, for convenience of explanation, in the drawings, the size of components may be exaggerated and/or reduced. Thus, the spatially relative terms “below,” “beneath,” “lower,” “above,” or “upper” may be used to easily describe a component correlation with other components.

Terms used to describe a space or a direction in this specification are terms for describing the space and direction shown in the drawings, but may be understood as terms for describing various other directions or various viewpoints. For example, when a device or component shown in the drawings is turned over, a device or component described “below” may be interpreted as being in a different orientation (e.g., rotated 90 degrees or in the opposite direction). For example, when a device or component shown in the drawings is turned over, a device or component described “on” may be interpreted as being in a different orientation (e.g., rotated 90 degrees or in the opposite direction). Accordingly, “below” and “on” may include both upward and downward directions. Devices or components may be oriented differently from the drawings, and descriptions of space or direction described herein may be interpreted in various ways.

A process order or method order understood in the description of processing processes or manufacturing methods in the disclosure may be different from the described order. For example, two processes described in succession may be performed substantially simultaneously, or may be performed in an order opposite to the order described.

In the following embodiments, the x-axis, y-axis, and z-axis are not limited to the three axes of the Cartesian coordinate system, and may be interpreted in a broad sense including them. For example, the x-axis, y-axis, and z-axis may be orthogonal to each other, but may refer to different directions that are not orthogonal to each other.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

When a component is referred to as “connected to” or “coupled to” another component, it is understood that the component is to be connected or coupled to the other component directly or indirectly.

Likewise, when a component is referred to as “electrically connected” to another component, the component and the other component may be directly and electrically connected, or may be indirectly and electrically connected through a conductive component.

When a component is referred to as being “between” two components, it is understood that the component is the only component placed between the two components, or that another component other than the one component is placed between the two components.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b or c” indicates only a, only b, only c, both a and b, both a and c, both b and c, all of a, b, and c, or variations thereof.

For example, the expressions “mix,” “mixture,” “mixing,” or “have” specify the presence of the described feature, integer, step, operation, element, and/or component, but do not exclude the presence or addition of one or more other features, integers, steps, operations, elements, components, and/or groups.

For example, terms such as “substantially,” “approximately,” and similar terms are used as terms of approximation rather than terms of degree, and describe inherent variations in measured or calculated values to be recognized by one of skill in the art. For example, use of the terms such as “may” may be used to mean “one or more embodiments disclosed herein.”

For example, in the disclosure, when one layer has the “same layer structure” as another layer, this may mean that a plurality of layers provided in one layer is to be provided in the same order in another layer. For example, a plurality of layers provided in one layer and a plurality of layers provided in another layer may each include the same material and be formed in the same order.

Electronic or electrical devices and/or any other related devices or components (e.g., some of various modules) according to embodiments described herein may be implemented with any suitable hardware, firmware (e.g., application-specific integrated circuit), software, and a combination thereof. For example, the various components of these devices may be formed on one integrated circuit (IC) chip or on separate IC chips. The various components of these devices may be formed on a flexible printed circuit film, a tape carrier package (TCP), a printed circuit board (PCB), or on a single substrate. The various components of these devices may be processes or threads, may be executed in one or more processors, may execute computer program instructions in one or more computing devices, and may interact with other system components for performing various functions described in the disclosure.

The computer program instructions are stored in a memory to be implemented in a computing device using standard memory devices, such as random access memory (RAM). The computer program instructions may also be stored on other non-transitory computer-readable media, such as a CD-ROM or a flash drive. One of skill in the art may understand that functions of various computing devices are coupled or integrated into a single computing device or that the functionality of a particular computing device is distributed over one or more other computing devices without departing from the spirit and scope of the embodiments.

Hereinafter, a display device according to embodiments of the disclosure will be described in detail with reference to the accompanying drawings.

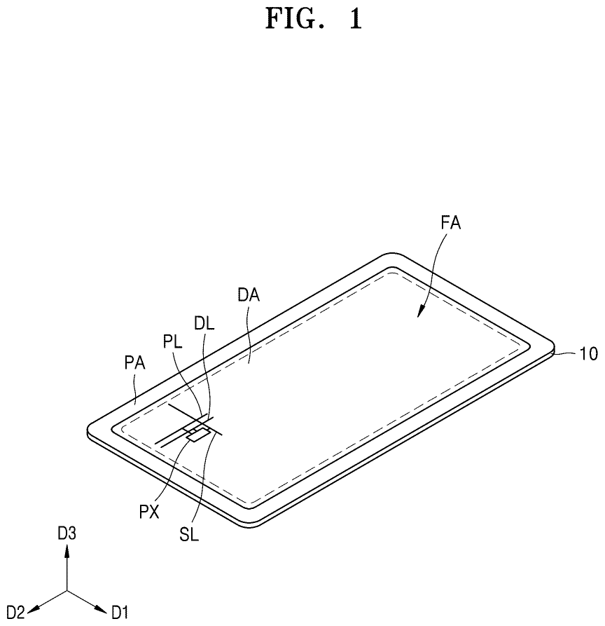

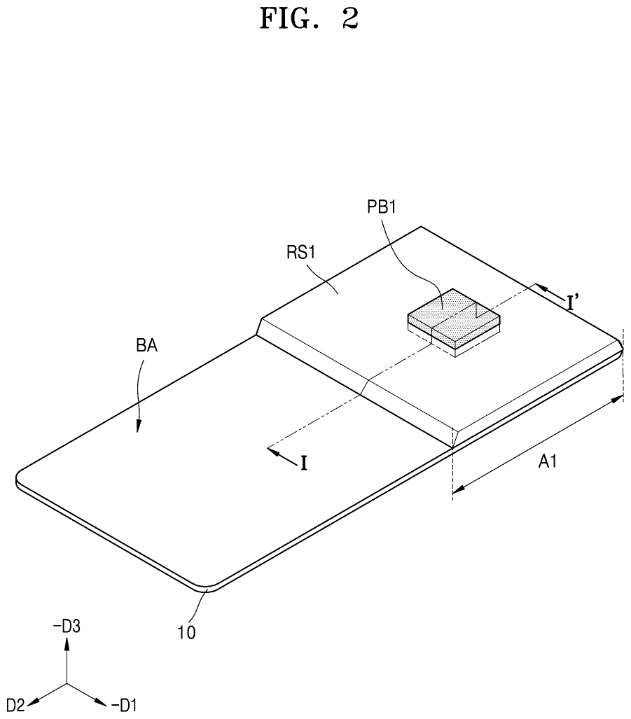

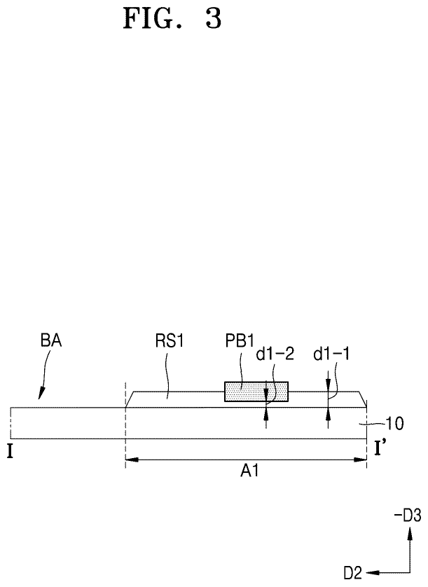

FIG. 1 is a schematic perspective view showing a display panel of a display device according to an embodiment, FIG. 2 is a schematic view showing the other surface (or rear surface) of the display panel of FIG. 1, and FIG. 3 is a cross-sectional view of an example of the display panel taken along line I-I′ of FIG. 2. In detail, FIG. 1 is a diagram showing one surface FA (or front surface) of a display panel.

As shown in FIGS. 1 and 2, a display device according to an embodiment may include a display panel 10. The display device may be any types of display device as long as the display device includes the display panel 10. In an embodiment, for example, the display device may be a various types of device such as a smartphone, tablet, laptop, television, or billboard. The display device according to an embodiment may include thin film transistors and capacitors, and the thin film transistors and the capacitors may be implemented by conductive layers and insulating layers provided or formed therein.

The display panel 10 includes a display area DA and a peripheral area PA located outside the display area DA. In an embodiment, as shown in FIG. 1, the display area DA may have a rectangular shape. However, the disclosure is not limited thereto. Alternatively, the display area DA may have one of other various shapes, such as a circle, an oval, a polygon, or a certain shape.

The display area DA may be a portion that displays an image and may include a plurality of pixels PX located therein. Each pixel PX may include a display element such as an organic light emitting diode. Each pixel PX may emit, for example, red, green, or blue light. The pixels PX may be connected to a pixel circuit including a thin film transistor TFT and a storage capacitor. The pixel circuit may be connected to a scan line SL configured to transmit a scan signal, a data line DL that crosses the scan line SL and is configured to transmit a data signal, and a driving voltage line PL configured to supply a driving voltage. The scan line SL may extend in an x direction (hereinafter referred to as a first direction D1), and the data line DL and the driving voltage line PL may extend in a y direction (hereinafter referred to as a second direction D2). Here, a third direction D3 may be a direction perpendicular to the first direction D1 and the second direction D2, and the third direction D3 may be a thickness direction of the display panel 10.

The pixel PX may emit light with a brightness corresponding to an electrical signal from an electrically connected pixel circuit. The display area DA may display a certain image through light emitted from the pixel PX. In an embodiment, as described above, the pixel PX may be defined as an emission area that emits light of any one color from among red, green, and blue.

The peripheral area PA is an area in which the pixel PX is not located and which does not display an image. Power supply wiring for driving the pixel PX may be located in the peripheral area PA. Pads may be located in the peripheral area PA, and an integrated circuit device such as a printed circuit board including a driving circuit or a driver IC may be located to be electrically connected to the plurality of pads.

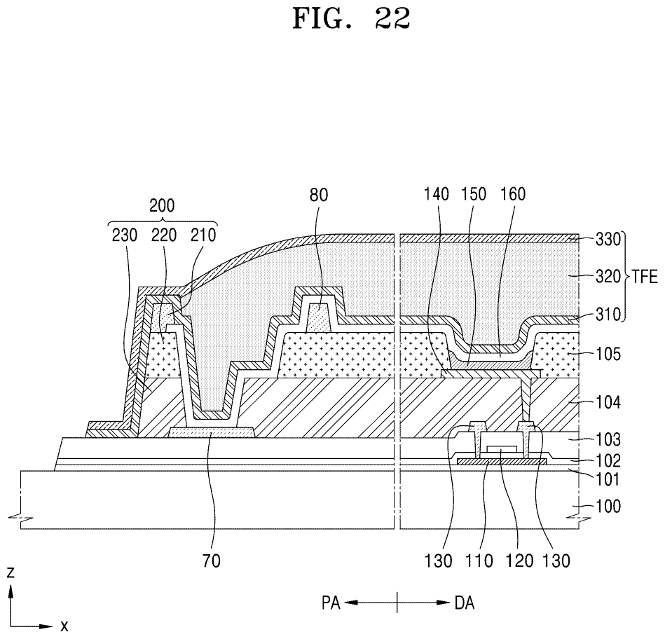

In an embodiment, the display panel 10 includes a substrate 100 (see FIG. 22), and thus the display area DA and the peripheral area PA may be defined on the substrate 100. Detailed features of the substrate 100 will be described below.

A plurality of transistors may be located in the display area DA. With regard to the plurality of transistors, depending on the type of transistor (N-type or P-type) and/or operating conditions, a first terminal of a transistor may be a source electrode or a drain electrode, and a second terminal may be an electrode different from the first terminal. In an embodiment, for example, the first terminal is a source electrode, and the second terminal may be a drain electrode.

The plurality of transistors may include a driving transistor, a data writing transistor, a compensation transistor, an initialization transistor, and a light emission control transistor. The driving transistor may be connected between the driving voltage line PL and an organic light emitting diode OLED, and the data writing transistor may be connected to the data line DL and the driving transistor and may perform a switching operation of transmitting a data signal to the data line DL.

The compensation transistor may be turned on in response to a scan signal received through the scan line SL and may compensate for a threshold voltage of the driving transistor by connecting the driving transistor to the organic light emitting diode OLED.

The initialization transistor may be turned on in response to the scan signal received through the scan line SL and may initialize a gate electrode of the driving transistor by transmitting an initialization voltage to the gate electrode of the driving transistor. The scan line connected to the initialization transistor may be a separate scan line that is different from the scan line connected to the compensation transistor.

The light emission control transistor may be turned on in response to a light emission control signal received through a light emission control line, and as a result, a driving current may flow in the organic light emitting diode OLED.

The organic light emitting diode OLED may include a pixel electrode (anode) and a counter electrode (cathode), and a counter electrode layer (see 160 of FIG. 22) may receive a second power voltage ELVSS. The organic light emitting diode OLED may display an image by receiving a driving current from the driving transistor and emitting light.

Hereinafter, an organic light emitting display device will be described as an example of a display device according to an embodiment, but the disclosure is not limited thereto. The display device according to another embodiment may be an inorganic light emitting display (or inorganic EL display device) or a display device such as a quantum dot light emitting display. For example, an emissive layer of the display element provided in the display device may include an organic material or an inorganic material. The display device may include an emissive layer and a quantum dot located on a path of the emissive layer.

In an embodiment, as shown in FIGS. 1 and 2, the display panel 10 may include one surface FA that displays (or define) a screen and an opposing surface BA located opposite to the one surface FA. In an embodiment, for example, the one side FA that displays the image may be a front surface (or a display surface) of the display panel 10, and the opposing surface BA located opposite to the one surface FA may be a rear surface of the display panel 10.

The opposing surface BA may include a first area A1. The first area A1 may be an area in which a first bonding target PB1, which will be described below, is located and may refer to an area in which resin is applied to fix the first bonding target PB1.

The first bonding target PB1 may be one of various components provided in the display device and located outside the display panel 10. In an embodiment, for example, the first bonding target PB1 may include various objects (e.g., elements or modules) such as a printed circuit board, a camera module, or a battery. The first bonding target PB1 may be located in the first area A1 of the opposing surface BA of the display panel 10.

A first resin layer RS1 may be located between the first bonding target PB1 and the opposing surface BA, and may be a component for bonding the first bonding target PB1. The first resin layer RS1 is cured after the first bonding target PB1 is located or disposed thereon, and thus the first bonding target PB1 may sink into the first resin layer RS1 to a certain depth. Then, as the curing result, at least a portion of a lateral surface of the first bonding target PB1 may be covered by the first resin layer RS1. The first resin layer RS1 may cover the entire lateral surface of the first bonding target PB1, or may cover a portion of the lateral surface of the first bonding target PB1. In an embodiment, for example, the first resin layer RS1 is cured after being applied to the other surface BA of the display panel 10, and thus an edge of the cured first resin layer RS1 may have an inclined shape.

In an embodiment, as shown in FIG. 3, the first resin layer RS1 may be located in the first area A1. The first resin layer RS1 may have a first first thickness (hereinafter, will be referred to as “1^{st}-1 thickness”) d1-1, and a distance between the first resin layer RS1 and the first bonding target PB1 may have a second first thickness (hereinafter, will be referred to as “1^{st}-2 thickness”) d1-2 that is less than the 1^{st}-1 thickness d1-1.

In an embodiment, for example, when viewed in a direction perpendicular to the opposing surface BA (or in the third direction D3), an area of the first resin layer RS1 may be greater than an area of the first bonding target PB1. In such an embodiment, the first resin layer RS1 may be applied wider than the first bonding target PB1 to cover at least a portion of the lateral surface of the first bonding target PB1, and thus firmly fix the first bonding target PB1.

The first resin layer RS1 may include one of optical curing resin, thermo-curing resin, hybrid resin, electron beam curing resin, and solvent curing resin.

The first resin layer RS1 functions as an adhesive layer that adheres the opposing surface BA of the display panel 10 and the first bonding target PB1. In other words, the first resin layer RS1 may be formed to fill a space between the opposing surface BA of the display panel 10 and the first bonding target PB1. In an embodiment, for example, the first resin layer RS1 may include optical curing resin (or optical bonding resin) to function as an adhesive layer. The first resin layer RS1 may include a material that obtains adhesiveness when applied to the opposing surface BA of the display panel 10 and then optically-cured or thermally-cured.

In such an embodiment, where the first resin layer RS1 is used as an adhesive layer, a separate pressing process may be omitted when the first bonding target PB1 is adhered unlike other types of adhesive layers. The first resin layer RS1 has adhesive properties while being cured through an optical curing process or a thermo-curing process, and thus the pressing process for adhering the first bonding target PB1 during a display manufacturing process may be omitted. As a result, defects or damage to the display panel 10 that may occur due to the pressing process may be effectively prevented. In such an embodiment, penetration of external moisture and external shock may be effectively prevented by the cured first resin layer RS1.

In an embodiment, for example, the first resin layer RS1 may include at least one selected from a resin having a polar group, such as rosin ester resin, phenol resin, xylene resin, xylene phenol resin, or terpene phenol resin, various petroleum resins such as aromatic resin with relatively low polarity, aliphatic-aromatic copolymer-based resin, or alicyclic resin, and common tackifying resins such as coumarone resin, low molecular weight polyethylene resin, terpene resin, or hydrogenated resin thereof.

In an embodiment, for example, the first resin layer RS1 may include, if desired, at least one selected from various additives such as an extender, a plasticizer, a moisture absorber, a condensation reaction accelerating catalyst, a photosensitizer, a photopolymerization accelerator, a curing catalyst, a physical property adjuster to improve tensile properties, a reinforcing agent, a coloring agent, a flame retardant, an anti-flow agent, an antioxidant, an anti-aging agent, an ultraviolet absorber, a solvent, a fragrance, a pigment, a dye, a filler, a diluent, a polymerization inhibitor, or a solid polymer.

Materials constituting the first resin layer RS1 may vary depending on a type of the first bonding target PB1. In an embodiment, for example, where the first bonding target PB1 is a component that generates heat, such as a printed circuit board, heat may be desired to be discharged by the first resin layer RS1. In such an embodiment, for more efficient heat dissipation, a material with high thermal conductivity (for example, a metallic material such as aluminum powder) may be mixed with the resin constituting the first resin layer RS1. In an embodiment, the first resin layer RS1 may include a mixture, and the mixture may be obtained by mixing resin and a metallic material.

In an embodiment, for example, where the first bonding target PB1 is a sensor that detects light, such as a camera module, the first resin layer RS1 may include transparent resin. In another embodiment, where the first resin layer RS1 is desired to block external light with respect to the first bonding target PB1, the first resin layer RS1 may include an opaque resin.

In embodiments of the disclosure, as described above, the physical properties of the applied resin may vary depending on the characteristics of the first bonding target PB1. As a result, the characteristics of the first resin layer RS1 also change, and the first resin layer RS1 suitable for the characteristics of the first bonding target PB1 may be formed.

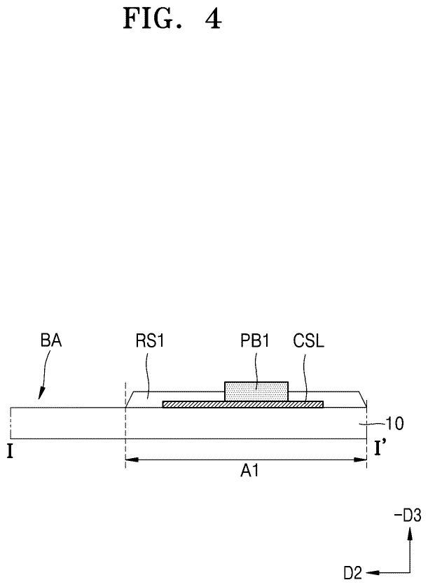

FIG. 4 is a cross-sectional view showing an example of a cross-section of the display panel taken along line I-I′ of FIG. 2.

For convenience of description, any repetitive detailed description of the elements of FIG. 4 that are substantially the same as those described above may be omitted.

As shown in FIG. 4, the display device according to an embodiment may further include a cushion layer located between the first resin layer RS1 and the opposing surface BA of the display panel 10. The cushion layer may include a same material as the first resin layer RS1. The cushion layer may be a layer cured via one of the above-described optical curing process, thermo-curing process, hybrid curing process, electron beam curing process, and solvent curing process.

In an embodiment, the coating layer CSL may cover the first area A1 or a portion of the first area A1 on the opposing surface BA of the display panel 10. The above-described first bonding target PB1 may be disposed on the coating layer CSL. In such an embodiment, the first resin layer RS1 may be formed to cover at least a portion of the lateral surface of the first bonding target PB1 after the first bonding target PB1 is located. As a result, the first resin layer RS1 covers an upper surface of the coating layer CSL and may not be located between the coating layer CSL and the first bonding target PB1. The first resin layer RS1 may cover the upper and lateral surfaces of the coating layer CSL, and when viewed in a direction perpendicular to the opposing surface BA of the display panel 10, an area of the first resin layer RS1 may be greater than an area of the coating layer CSL.

In an embodiment, as shown in FIG. 4, the first resin layer RS1 may not cover the upper surface of the first bonding component, but not being limited thereto. In another embodiment, the first resin layer RS1 may cover an upper surface of the first bonding target PB1 by using the thickness of the coating layer CSL. In some cases, the first resin layer RS1 may cover a portion of the upper surface of the first bonding target PB1.

The coating layer CSL may be a component for preventing direct contact between the opposing surface BA of the display panel 10 and the first bonding target PB1. That is, the coating layer CSL may be a component for protecting the opposing surface BA of the display panel 10 from the first bonding target PB1. In such an embodiment, the impact applied to the first bonding target PB1 due to an external force or the like may not be directly transmitted to the display panel 10 by the coating layer CSL, and thus the display panel 10 may be protected by the coating layer CSL.

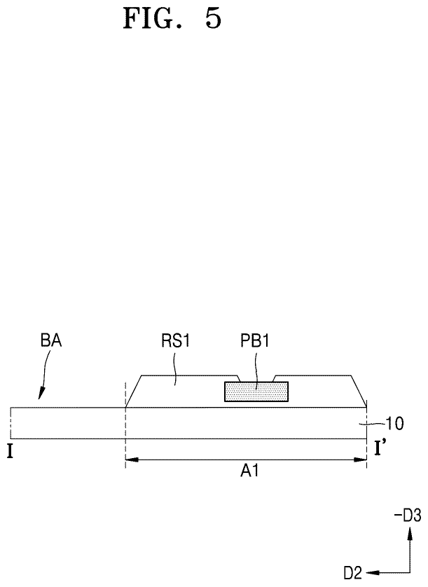

FIG. 5 is a cross-sectional view showing an example of a cross-section of the display panel taken along line I-I′ of FIG. 2.

For convenience of description, any repetitive detailed description of the elements of FIG. 5 that are substantially the same as those described above may be omitted.

In an embodiment, as shown in FIG. 5, the first resin layer RS1 may cover the lateral surface of the display panel 10 and cover at least a portion of the upper surface of the first bonding target PB1. For convenience of illustration and description, the first resin layer RS1 is shown in FIG. 5 to cover a portion of the upper surface of the first bonding target PB1, but in some cases, the first resin layer RS1 may cover the entire upper surface of the first bonding target PB1.

In an embodiment, as shown in FIG. 5, the thickness of the first resin layer RS1 may be greater than the thickness of the first bonding target PB1. In such an embodiment, after the resin of the first resin layer RS1 is applied on the opposing surface BA, the first bonding target PB1 may be disposed on the applied resin, and in this case, the thickness of the applied resin may be greater than the thickness of the first bonding target PB1. After the first bonding target PB1 is located, the curing process may not begin for a certain period of time until the first bonding target PB1 sufficiently sinks between the applied resins. The curing process may begin after the first bonding target PB1 sufficiently sinks between the applied resins, and as a result, as shown in FIG. 5, the first resin layer RS1 may cover the upper surface or at least a portion of the upper surface of the first bonding target PB1.

In such an embodiment, where the upper surface or at least a portion of the upper surface of the first bonding target PB1 is covered by the first resin layer RS1, the first bonding target PB1 may be more firmly attached. The first bonding target PB1 may be safer from external shock applied to the first bonding target PB1. External shocks applied to the first bonding target PB1 may be applied from various directions, and thus the first resin layer RS1 may cover at least a portion of the upper surface of the first bonding target PB1.

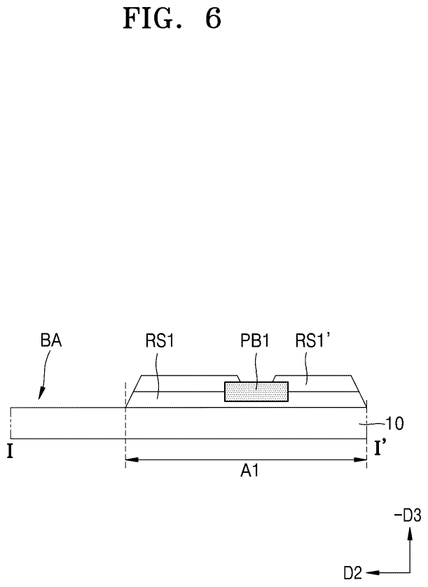

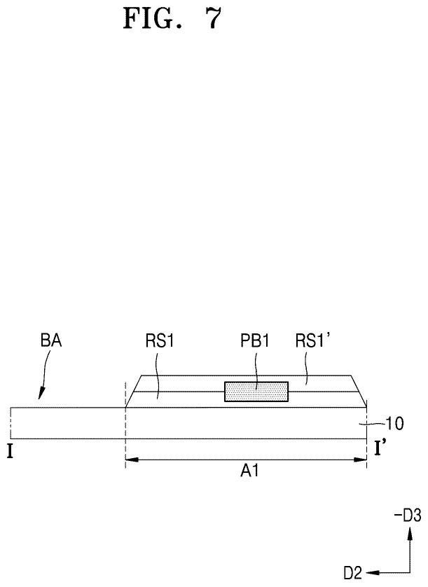

FIG. 6 is a cross-sectional view showing an example of a cross-section of the display panel taken along line I-I′ of FIG. 2, and FIG. 7 is a cross-sectional view showing an example of a cross-section of the display panel taken along line I-I′ of FIG. 2.

For convenience of description, any repetitive detailed description of the elements of FIGS. 6 and 7 that are substantially the same as those described above may be omitted.

In an embodiment, as shown in FIGS. 6 and 7, a first upper resin layer RS1′ may be further disposed on the first resin layer RS1. The first upper resin layer RS1′ may cover a portion of the lateral surface of the first bonding target PB1, or may cover at least a portion of the upper surface of the first bonding target PB1.

The first upper resin layer RS1′ may be formed after the first resin layer RS1 is cured. Therefore, the resin of the first resin layer RS1 may be applied, the first bonding target PB1 may be disposed on the applied resin, and after the first bonding target PB1 is located, the first resin layer RS1 may be cured. After the first resin layer RS1 is cured, resin may be applied to cover the upper surface of the first resin layer RS1 and the upper surface (or at least a portion of the upper surface) of the first bonding target PB1, and when the applied resin is cured, the first upper resin layer RS1′ is formed.

In an embodiment, as shown in FIG. 5, the upper surface of the first bonding target PB1 may be covered by the first resin layer RS1, but this may be possible when the thickness of the first bonding target PB1 is sufficiently thin. In an embodiment, a separate first upper resin layer RS1′ may be further located as shown in FIGS. 6 and 7 such that the upper surface or at least a portion of the upper surface of a bonded target may be effectively covered without being limited by the thickness of the bonded target.

In such an embodiment, where the upper surface or at least a portion of the upper surface of the first bonding target PB1 is covered by the first upper resin layer RS1′, the first bonding target PB1 may be more firmly attached. The first bonding target PB1 may be safer from external shock applied to the first bonding target PB1. External shocks applied to the first bonding target PB1 may be applied from various directions, and thus the first upper resin layer RS1′ may cover at least a portion of the upper surface of the first bonding target PB1.

In an embodiment, as shown in FIGS. 6 and 7, the characteristics of the resins constituting each of the first resin layer RS1 and the first upper resin layer RS1′ disposed on the first resin layer RS1 may be different from each other. In an embodiment, for example, where the first bonding target PB1 generates heat, the first resin layer RS1 may include a mixture of resin and a metallic material, and the first upper resin layer RS1′ may also include a mixture of resin and a metallic material. In such an embodiment, to increase heat generation efficiency, the mixture of the first upper resin layer RS1′ may include more metallic materials than the mixture of the first resin layer RS1. In such an embodiment, heat of the first bonding target PB1 may be dissipated to the outside more efficiently.

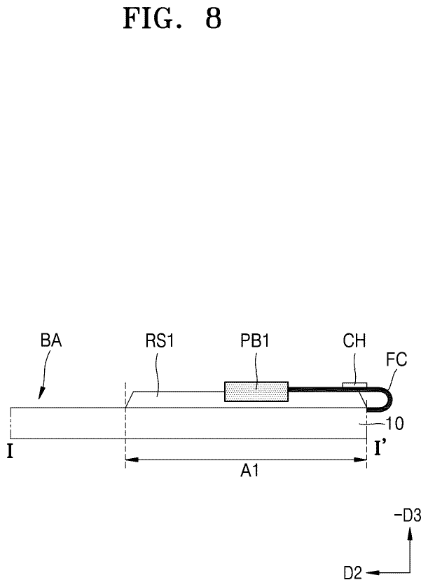

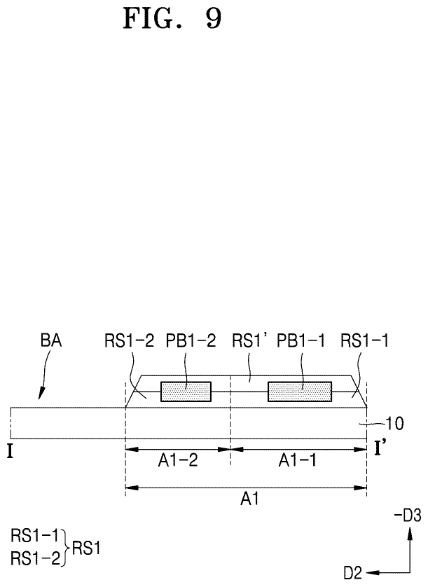

FIG. 8 is a cross-sectional view showing an example of a cross-section of the display panel taken along line I-l′ of FIG. 2, and FIG. 9 is a cross-sectional view showing an example of a cross-section of the display panel taken along line I-I′ of FIG. 2.

For convenience of description, any repetitive detailed description of the elements of FIGS. 8 and 9 that are substantially the same as those described above may be omitted.

In an embodiment, as shown in FIG. 8, the first bonding target PB1 may be a printed circuit board. In such an embodiment where the first bonding target PB1 is a printed circuit board, the display device may further include an integrated circuit film FC that is connected to the display panel 10 and on which a driving integrated circuit CH is mounted. The first bonding target PB1, which is a printed circuit board, may be connected to the integrated circuit film FC.

The integrated circuit film FC may be flexible. As a result, even if the printed circuit board is adhered to the opposing surface BA of the display panel 10, the printed circuit board and the display panel 10 may be electrically connected to each other by the flexible integrated circuit film FC.

As shown in FIG. 9, the opposing surface BA of the display panel 10 may include the first area A1, which is a portion covered by the first resin layer RS1, and the first area A1 may include a first first area (hereinafter, will be referred to as “1^{st}-1 area”) A1-1 and a second first area (hereinafter, will be referred to as “1^{st}-2 area”) A1-2.

In an embodiment, for example, the 1^{st}-1 area A1-1 may refer to an area from one edge of the display panel 10 to a certain boundary line spaced a certain distance away. In an embodiment, for example, the 1^{st}-1 area A1-1 may be an area in which a first first bonding target (hereinafter, will be referred to as “1^{st}-1 bonding target”) PB1-1 is located.

In an embodiment, for example, the 1st-2 area A1-2 may be an area located around the 1st-1 area A1-1, and the sum of the 1^{st}-1 area A1-1 and the 1st-2 area A1-2 may be the first area A1. In an embodiment, for example, the 1^{st}-2 area A1-2 may refer to an area from one boundary of the 1^{st}-1 area A1-1 to another certain boundary line spaced a certain distance away. In an embodiment, for example, the 1^{st}-2 area A1-2 may be an area in which a second first bonding target (hereinafter, will be referred to as “1^{st}-2 bonding target”) PB1-2 is located.

The first resin layer RS1 may include a first first resin layer (hereinafter, will be referred to as “1^{st}-1 resin layer”) RS1-1 located in the 1^{st}-1 area A1-1, and a second first resin layer (hereinafter, will be referred to as “1^{st}-2 resin layer”) RS1-2 located in the 1^{st}-2 area A1-2. The 1^{st}-1 resin layer RS1-1 and the 1^{st}-2 resin layer RS1-2 may be disposed in (or directly on) a same layer as each other and may include a same material as each other.

In an embodiment, for example, the 1^{st}-1 resin layer RS1-1 may be cured using a first method. The first method may be one of the above-described optical curing process, thermo-curing process, hybrid curing process, electron beam curing process, and solvent curing process. The 1^{st}-2 resin layer RS1-2 may be cured using a second method. The second method may be one of the above-described optical curing process, thermo-curing process, hybrid curing process, electron beam curing process, and solvent curing process. In this case, the second method may be different from the first method.

Alternatively, the 1^{st}-1 resin layer RS1-1 and the 1^{st}-2 resin layer RS1-2 may be cured in a same manner but under different conditions. In an embodiment, for example, where both the 1^{st}-1 resin layer RS1-1 and the 1^{st}-2 resin layer RS1-2 are cured using a thermo-curing process, the 1^{st}-1 resin layer RS1-1 may be thermo-cured (or thermally cured) at a first temperature, and the 1^{st}-2 resin layer RS1-2 may be thermo-cured at a second temperature.

In another embodiment, for example, where both the 1^{st}-1 resin layer RS1-1 and the 1^{st}-2 resin layer RS1-2 are cured using an optical curing process, the 1^{st}-1 resin layer RS1-1 may be optical-cured (or optically cured) at a first wavelength, and the 1^{st}-2 resin layer RS1-2 may be optical-cured at a second wavelength. Different light sources may be used in each of the 1^{st}-1 area A1-1 and the 1^{st}-2 area A1-2.

The 1^{st}-1 resin layer RS1-1 may cover a lateral surface or at least a portion of the lateral surface of the 1^{st}-1 bonding target PB1-1. The 1^{st}-2 resin layer RS1-2 may cover a lateral surface or at least a portion of the lateral surface of the 1^{st}-2 bonding target PB1-2. The 1^{st}-1 bonding target PB1-1 may be disposed on the 1^{st}-1 resin layer RS1-1 and may sink to a certain depth. After the 131-1 bonding target PB1-1 sinks to a certain depth in the 1^{st}-1 resin layer RS1-1, a curing process may begin. The 1^{st}-2 bonding target PB1-2 may be disposed on the 1^{st}-2 resin layer RS1-2 and may sink to a certain depth. After the 1^{st}-2 bonding target PB1-2 sinks to a certain depth in the 1^{st}-2 resin layer RS1-2, a curing process may begin.

In an embodiment, as shown in FIG. 9, the first upper resin layer RS1′ may be disposed on the 1^{st}-1 resin layer RS1-1 and the 1^{st}-2 resin layer RS1-2. The first upper resin layer RS1′ may be disposed on the 1^{st}-1 bonding target PB1-1 and the 1^{st}-2 bonding target PB1-2. The first upper resin layer RS1′ may cover an upper surface or at least a portion of the upper surface of the 1^{st}-1 bonding target PB1-1. The first upper resin layer RS1′ may cover an upper surface or at least a portion of the upper surface of the 1^{st}-2 bonding target PB1-2. The first upper resin layer RS1′ may cover a portion of the lateral surface of the 1^{st}-1 bonding target PB1-1 depending on the thickness of the 1^{st}-1 resin layer RS1-1. The first upper resin layer RS1′ may cover a portion of the lateral surface of the 1^{st}-2 bonding target PB1-2 depending on the thickness of the 1^{st}-2 resin layer RS1-2. The first upper resin layer RS1′ may cover an upper surface of the 1^{st}-1 resin layer RS1-1 and an upper surface of the 1^{st}-2 resin layer RS1-2.

According to a difference in the curing methods of the 1^{st}-1 resin layer RS1-1 and the 1^{st}-2 resin layer RS1-2, the characteristics of the 1^{st}-1 resin layer RS1-1 and the 1^{st}-2 resin layer RS1-2 may vary or different form each other, that is, may be set independently of each other. In an embodiment, for example, the 1^{st}-1 resin layer RS1-1 corresponding to the 1^{st}-1 bonding target PB1-1 may be cured using an optical curing process, and the 1^{st}-2 resin layer RS1-2 corresponding to the 1^{st}-2 bonding target PB1-2 may be cured using a thermo-curing process. In such an embodiment, it may be difficult to apply high-temperature heat due to the characteristics of the display panel 10, and thus the hardness of the 1^{st}-1 resin layer RS1-1 may be higher than the hardness of the 1^{st}-2 resin layer RS1-2. Accordingly, the curing method of the 1^{st}-1 resin layer RS1-1 and the 1^{st}-2 resin layer RS1-2 may vary depending on whether higher hardness is desired. As such, adjacent resin layers may have different characteristics from each other due to a difference in curing methods.

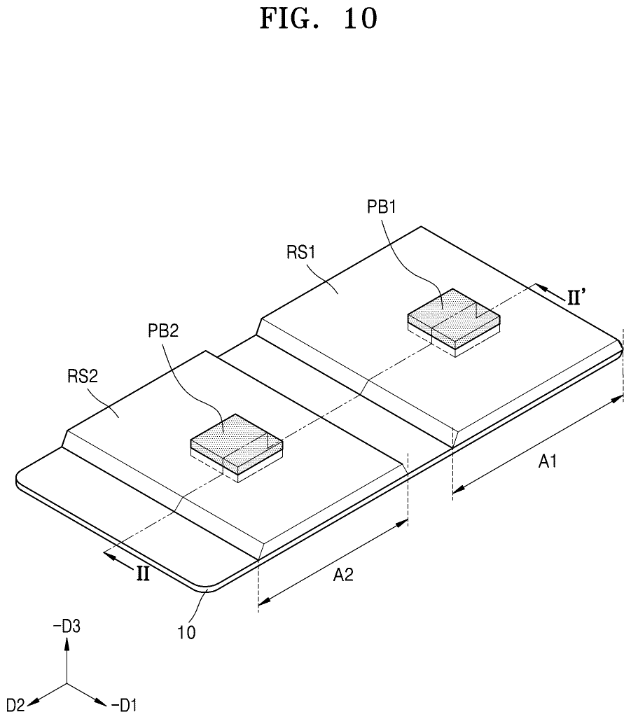

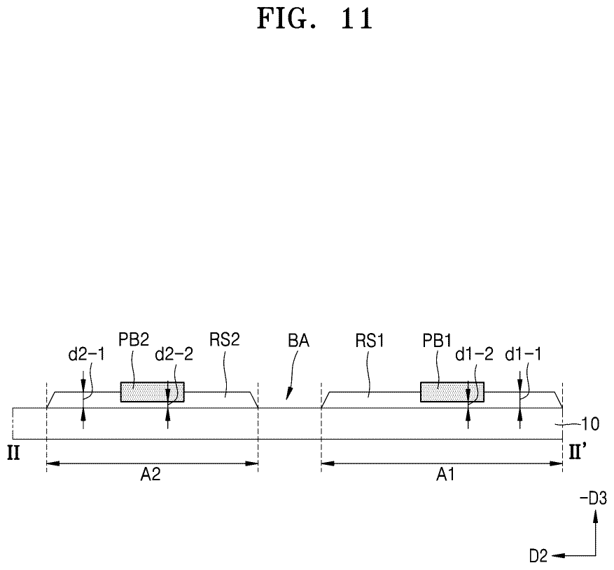

FIG. 10 is a schematic diagram showing another example of another surface (or rear surface) of the display panel of FIG. 1, and FIGS. 11 to 13 are diagrams showing examples of a cross-section of the display panel taken along line II-II′ of FIG. 10.

For convenience of description, any repetitive detailed description of the elements of FIGS. 10 to 13 that are substantially the same as those described above may be omitted.

In an embodiment, as shown in FIGS. 10 and 11, the opposing surface BA of the display panel 10 may include a first area A1 and a second area A2. The first area A1 may be one area of the opposing surface BA of the display panel 10. The first area A1 may be an area including an area (and a surrounding area thereof) of the opposing surface BA of the display panel 10, in which the first bonding target PB1 is located.

The second area A2 may be another area of the opposing surface BA of the display panel 10. The second area A2 may be an area located around the first area A1. The second area A2 may be an area spaced apart from the first area A1 by a certain distance. The display panel 10 may be an area including an area (and a surrounding area thereof) of the opposing surface BA of the display panel 10, in which a second bonding target PB2 is located.

The first resin layer RS1 may be located in the first area A1 of the opposing surface BA of the display panel 10. The first upper resin layer RS1′ may be located in the second area A2 of the opposing surface BA of the display panel 10. As a result, the first resin layer RS1 and the first upper resin layer RS1′ may be disposed in or (directly on) a same layer as each other. The first resin layer RS1 and the first upper resin layer RS1′ may be spaced apart from each other by a certain distance. Composition of a resin material constituting the first resin layer RS1 and composition of a resin material constituting the first upper resin layer RS1′ may be different from each other. The curing method of the first resin layer RS1 and the curing method of the first upper resin layer RS1′ may be different from each other.

In FIGS. 10 and 11, for convenience of illustration and description, the first bonding target PB1 and the second bonding target PB2 are shown as being located on a same line (e.g., line II-II′), but the first bonding target PB1 and the second bonding target PB2 are shown as being located at different locations, that is, not aligned with each other in the second direction D2.

In an embodiment, as shown in FIG. 11, the first resin layer RS1 may be located in the first area A1. The first resin layer RS1 may have a first first thickness (hereinafter, will be referred to as “1^{st}-1 thickness”) d1-1, and a distance between the first resin layer RS1 and the first bonding target PB1 may have a second first thickness (hereinafter, will be referred to as “1^{st}-2 thickness”) d1-2 that is less than the 1^{st}-1 thickness d1-1.

The second resin layer RS2 may be located in the second area A2. The second resin layer RS2 may have a first second thickness (hereinafter, will be referred to as “2^{nd}-1 thickness”) d2-1, and a distance between the second resin layer RS2 and the second bonding target PB2 may have a second second thickness (hereinafter, will be referred to as “2^{nd}-2 thickness”) d2-2 that is less than the 2^{nd}-1 thickness d2-1.

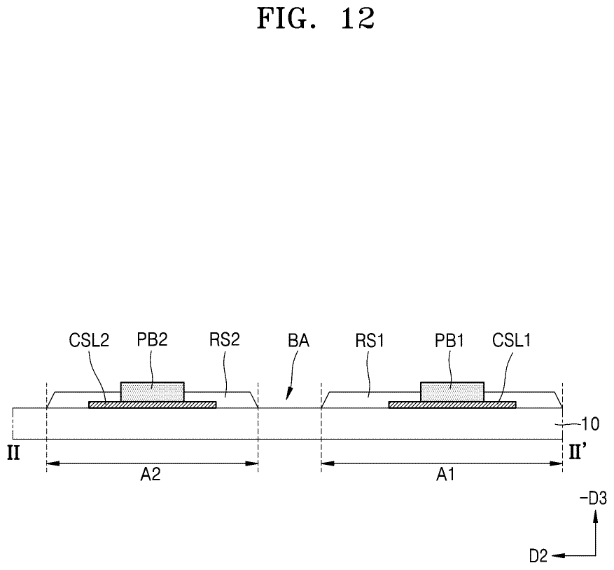

In an embodiment, as shown in FIG. 12, a first coating layer CSL1 may be located between the 1^{st}-1 resin layer RS1-1 and the first bonding target PB1. The first coating layer CSL1 may be located to cover a portion of the first area A1 of the opposing surface BA of the display panel 10. A second coating layer CSL2 may be located to cover a portion of the second area A2 of the opposing surface BA of the display panel 10.

When viewed in a direction perpendicular to the opposing surface BA of the display panel 10, that is, in the third direction D3, an area of the first coating layer CSL1 may be greater than an area of the first bonding target PB1. When viewed in a direction perpendicular to the opposing surface BA of the display panel 10, an area of the first coating layer CSL1 may be less than an area of the first resin layer RS1. When viewed in a direction perpendicular to the opposing surface BA of the display panel 10, an area of a second coating layer CSL2 may be greater than an area of the second bonding target PB2. When viewed in a direction perpendicular to the opposing surface BA of the display panel 10, an area of the second coating layer CSL2 may be less than an area of the first upper resin layer RS1′.

The first coating layer CSL1 and the second coating layer CSL2 may have a same characteristics as the above-described coating layer CSL, and thus any repetitive detailed description thereof will be omitted.

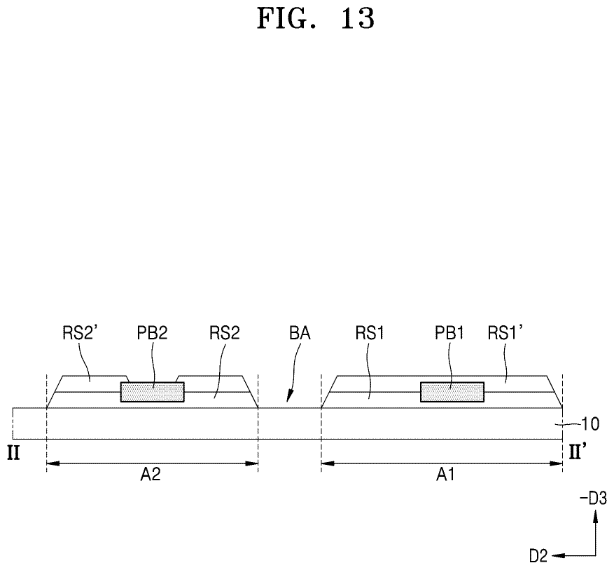

In an embodiment, as shown in FIG. 13, the first upper resin layer RS1′ may be disposed on the first resin layer RS1. The first upper resin layer RS1′ may cover a portion of the lateral surface of the first bonding target PB1, or may cover at least a portion of the upper surface of the first bonding target PB1.

The first upper resin layer RS1′ may be formed after the first resin layer RS1 is cured. Therefore, the resin of the first resin layer RS1 may be applied, the first bonding target PB1 may be disposed on the applied resin, and after the first bonding target PB1 is located, the first resin layer RS1 may be cured. After the first resin layer RS1 is cured, resin may be applied to cover the upper surface of the first resin layer RS1 and the upper surface (or at least a portion of the upper surface) of the first bonding target PB1, and when the applied resin is cured, the first upper resin layer RS1′ is formed.

In such an embodiment, as described above with reference to FIG. 5, the upper surface of the first bonding target PB1 may be covered by the first resin layer RS1, but this may be possible when the thickness of the first bonding target PB1 is sufficiently thin. Accordingly, when an upper surface or at least a portion of the upper surface of a bonding target is covered without being limited by the thickness of the bonding target, a separate first upper resin layer RS1′ may be further located.

In such an embodiment, where the upper surface or at least a portion of the upper surface of the first bonding target PB1 is covered by the first upper resin layer RS1′, the first bonding target PB1 may be more firmly attached. The first bonding target PB1 may be safer from external shock applied to the first bonding target PB1. External shocks applied to the first bonding target PB1 may be applied from various directions, and thus the first upper resin layer RS1′ may cover at least a portion of the upper surface of the first bonding target PB1.

A second upper resin layer RS2′ may be disposed on the second resin layer RS2. The second upper resin layer RS2′ may cover a portion of the lateral surface of the second bonding target PB2, or may cover at least a portion of the upper surface of the second bonding target PB2.

The second upper resin layer RS2′ may be formed after the second resin layer RS2 is cured. Therefore, the resin of the second resin layer RS2 may be applied, the second bonding target PB2 may be disposed on the applied resin, and after the second bonding target PB2 is located, the second resin layer RS2 may be cured. After the second resin layer RS2 is cured, resin may be applied to cover the upper surface of the second resin layer RS2 and the upper surface (or at least a portion of the upper surface) of the second bonding target PB2, and when the applied resin is cured, the second upper resin layer RS2′ is formed.

In such an embodiment, as described above, the upper surface of the second bonding target PB2 may be covered by the second resin layer RS2, but this may be possible when the thickness of the second bonding target PB2 is sufficiently thin. Accordingly, when an upper surface or at least a portion of the upper surface of a bonding target is covered without being limited by the thickness of the bonding target, a separate second upper resin layer RS2′ may be further located.

In such an embodiment, where the upper surface or at least a portion of the upper surface of the second bonding target PB2 is covered by the second upper resin layer RS2′, the second bonding target PB2 may be more firmly attached. The second bonding target PB2 may be safer from external shock applied to the second bonding target PB2. External shocks applied to the second bonding target PB2 may be applied from various directions, and thus the second upper resin layer RS2′ may cover at least a portion of the upper surface of the second bonding target PB2.

In an embodiment of the display device according to the disclosure, a bonding target may be allowed to be effectively bonded to the opposing surface BA of the display panel 10 depending on the type or characteristics of the bonding target. A resin layer suitable for the type or characteristics of the bonding target may be formed by mixing another material with the resin or changing the curing method. A shape of the resin layer and an area covering the target to which the resin layer is bonded may be adjusted. That is, in the case of the first bonding target PB1 in the first area A1 and the second bonding target PB2 in the second area A2, areas covered by the corresponding resin layers may be different from each other. In an embodiment, for example, the first bonding target PB1 is a printed circuit layer, and thus the entire upper surface of the first bonding target PB1 may be covered by the first upper resin layer RS1′ for safer protection. In an embodiment, for example, the second bonding target PB2 is a camera module, and thus a lens area may need not be hidden, a portion of the upper surface may be covered by the second upper resin layer RS2′.

Hereinafter, a method of manufacturing a display device (hereinafter referred to as manufacturing method) according to an embodiment will be described in detail. For reference, in a description of the manufacturing method, any repetitive detailed description of the same or like elements as those of the display device described above may be omitted or simplified.

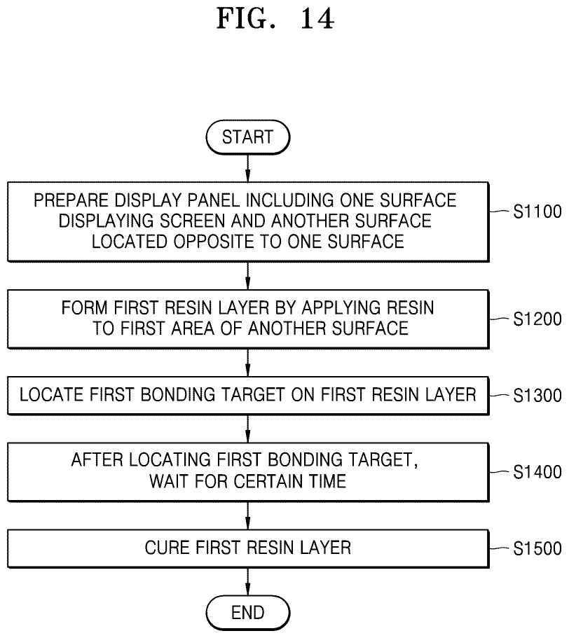

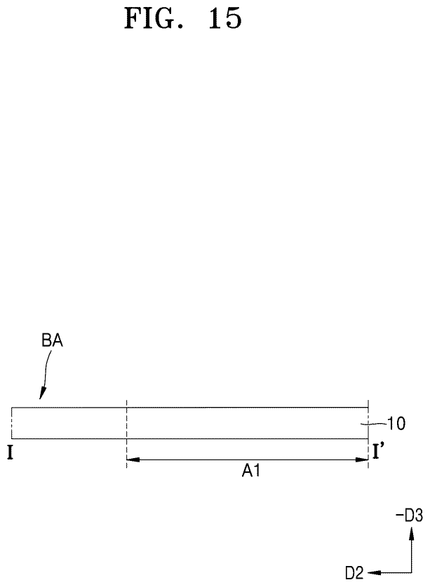

FIG. 14 is a schematic flowchart showing a method of manufacturing a display device according to an embodiment, and FIGS. 15 to 18 are diagrams showing the display panel 10 manufactured according to the flowchart of FIG. 14 in order.

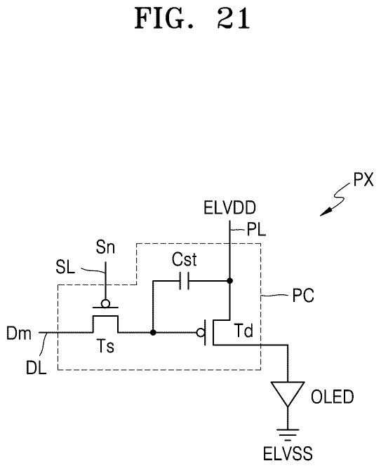

As shown in FIGS. 14 and 15, the manufacturing method according to an embodiment may include preparing the display panel 10 including the one surface FA displaying or defining a screen and another surface (or the opposing surface) BA located opposite to the one surface FA (S1100). A detailed features of the structure of an embodiment of the display panel 10 will be described below with reference to FIGS. 21 and 22.

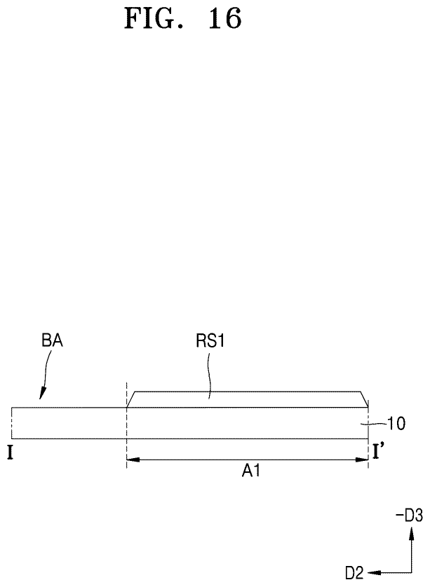

As shown in FIGS. 14 and 16, the manufacturing method according to an embodiment may further include forming the first resin layer RS1 by applying resin to the first area A1 of the opposing surface BA (S1200). The resin applied to the first area A1 may be applied in a liquid state. Before curing, the resin may be in a highly viscous liquid state.

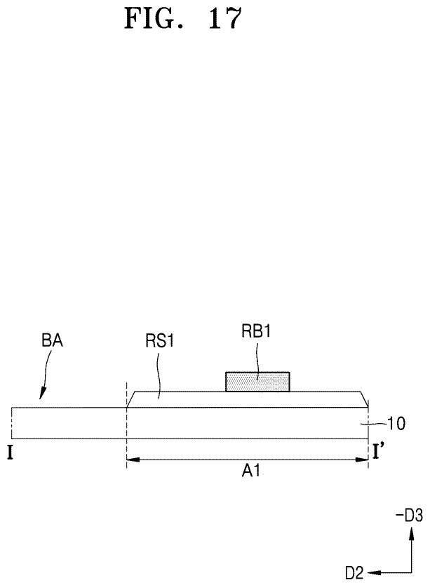

As shown in FIGS. 14 and 17, the manufacturing method according to an embodiment may further include disposing the first bonding target PB1 on the first resin layer RS1 (S1300). The first bonding target PB1 may be located on resin that is in a highly viscous liquid state. In this case, when viewed in a direction perpendicular to the opposing surface BA of the display panel 10, an area of the first resin layer RS1 may be greater than an area of the first bonding target PB1.

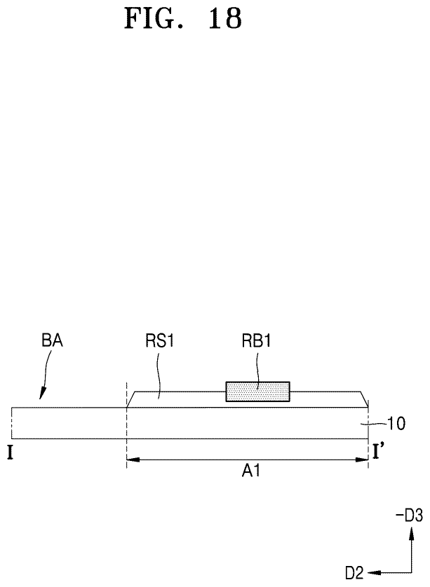

As shown in FIGS. 14 and 18, the manufacturing method according to an embodiment may further include after the locating the first bonding target PB1 on the first resin layer RS1, waiting for a certain time (S1400) and curing the first resin layer RS1 (S1500).

When locating the first bonding target PB1 on the first resin layer RS1 and then waiting for a certain time, the first bonding target PB1 may sink into the resin to a certain depth. When the first resin layer RS1 is cured before the first bonding target PB1 completely sinks, the first resin layer RS1 may be cured while the first bonding target PB1 sinks to a desired level. As a result, at least a portion of a lateral surface of the first bonding target PB1 may be covered by the first resin layer RS1. Depending on a sinking depth or the waiting time, the upper surface or at least a portion of the upper surface of the first bonding target PB1 may be covered by the first resin layer RS1.

As such, the depth at which the bonding target sinks may be easily controlled by adjusting a waiting time after locating the target on the first resin layer RS1.

In an embodiment, the manufacturing method may further include forming a cushion layer on the opposing surface BA prior to forming the first resin layer RS1. In this case, the forming of the first resin layer RS1 may be an operation of applying resin on the opposing surface BA and the cushion layer CSL. In such an embodiment, the cushion layer CSL is substantially the same as that described above. In this case, when viewed in a direction perpendicular to the opposing surface BA of the display panel 10, an area of the first resin layer RS1 may be greater than an area of the first bonding target PB1, and when viewed in a direction perpendicular to the opposing surface BA of the display panel 10, an area of the first resin layer RS1 may be less than an area of the cushion layer.

In an embodiment, for example, the first resin layer RS1 may include optical curing resin or thermo-curing resin. That is, the first resin layer RS1 may include another type of curing resin if desired. Alternatively, the first resin layer RS1 may include a mixture of optical curing resin or thermo-curing resin and a metallic material.

In an embodiment of the manufacturing method, the second resin layer RS2 may be further formed in the second area A2 as shown in FIGS. 10 and 11 described above. In an embodiment, for example, the manufacturing method according to an embodiment of the disclosure may further include forming the second resin layer RS2 by applying resin to the second area A2 located around the first area A1 of the opposing surface BA of the display panel 10. Then, the control method may further include locating the second bonding target PB2 on the second resin layer RS2.

The manufacturing method according to an embodiment of the disclosure may further include waiting for a certain time after locating the second bonding target PB2 and curing the second resin layer RS2. In this case, the first resin layer RS1 in the first area A1 may include one of optical curing resin and thermo-curing resin, and the second resin layer RS2 in the second area A2 may include the other of optical curing resin and thermo-curing resin. That is, the first resin layer RS1 and the second resin layer RS2 may include the same material (resin), but may also include materials (resin) having different characteristics.

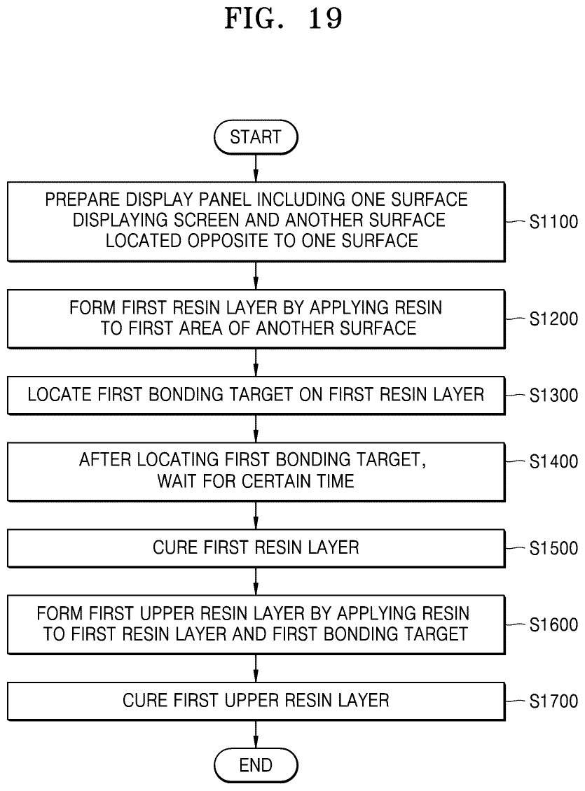

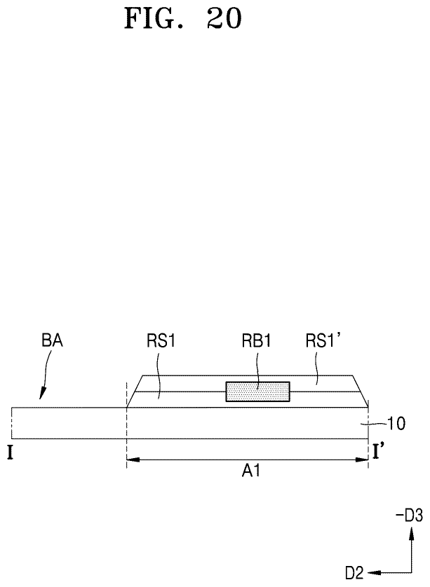

FIG. 19 is a schematic flowchart showing a manufacturing method of a display device according to an embodiment, and FIG. 20 is a diagram showing the display panel 10 on which the first upper resin layer RS1′ of FIG. 19 is formed.

For convenience of description, any repetitive detailed description of the elements of FIGS. 19 and 20 that are substantially the same as those described above may be omitted.

As shown in FIG. 19, the manufacturing method according to an embodiment may further include forming the first upper resin layer RS1′ by applying resin on the first resin layer RS1 and the first bonding target PB1 (S1600) and curing the first upper resin layer RS1′ (S1700). The applied resin may be a highly viscous liquid. The resin may be applied centered on the first bonding target PB1. The resin may be applied to cover a lateral surface of the first bonding target PB1 and at least a portion of the upper surface of the first bonding target PB1. After the resin is applied, the first upper resin layer RS1′ may be cured using the curing method described above. The curing method may vary depending on the type of bonding target.

Hereinafter, the structure of an embodiment of the display panel 10 will be described in detail. This is merely an example of the display panel 10, and embodiments of the disclosure are not limited thereto.

FIG. 21 is a schematic equivalent circuit diagram showing an embodiment of a pixel of the display device of FIG. 1.

In an embodiment, as shown in FIG. 21, each pixel PX includes a pixel circuit PC connected to the scan line SL and the data line DL, and an organic light emitting device OLED connected to the pixel circuit PC.

In an embodiment, for example, the pixel circuit PC includes a driving thin film transistor Td, a switching thin film transistor Ts, and a storage capacitor Cst. The switching thin film transistor Ts is connected to the scan line SL and the data line DL, and a data signal Dm input through the data line DL is transmitted to the driving thin film transistor Td in response to a scan signal Sn input through the scan line SL.

In an embodiment, for example, the storage capacitor CST is connected to the switching thin film transistor Ts and the driving voltage line PL, and stores a voltage corresponding to a difference between a voltage received from the switching thin film transistor Ts and a first power voltage ELVDD (or driving voltage) applied to the driving voltage line PL.

In an embodiment, for example, the driving thin film transistor Td may be connected to the driving voltage line PL and the storage capacitor Cst, and control a driving current flowing in the organic light emitting device OLED from the driving voltage line PL in response to the voltage value stored in the storage capacitor Cst. The organic light emitting device OLED may emit light with a certain brightness corresponding to the driving current.

The organic light emitting device OLED may receive a second power voltage ELVSS (or common voltage). In an embodiment, for example, the organic light emitting device OLED may receive the second power supply voltage ELVSS (common voltage) through a counter electrode (cathode), and the organic light emitting device OLED may emit light with a certain brightness corresponding to the driving current depending on a voltage difference between the first power voltage ELVDD (or driving voltage) and the second power supply voltage ELVSS (or common voltage).

In an embodiment, as shown in FIG. 21, the pixel circuit PC may include two thin film transistors and one storage capacitor, but the disclosure is not limited thereto. In another embodiment, for example, the pixel circuit PC may include two or more storage capacitors, as well as three or more thin film transistors.

FIG. 22 is a schematic cross-sectional view showing a portion of the display device of FIG. 1.

As described above, in an embodiment, the substrate 100 may include areas corresponding to the display area DA and the peripheral area PA outside the display area DA. The substrate 100 may include various flexible or bendable materials. In an embodiment, for example, the substrate 100 may include glass, metal, or polymer resin. The substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may be modified in various ways, and for example, may have a multilayer structure including two layers each containing such polymer resin and a barrier layer located between the layers and including an inorganic material (such as silicon oxide, silicon nitride, or silicon oxynitride).

A buffer layer 101 may be disposed on the substrate 100. The buffer layer 101 may function as a barrier layer and/or a blocking layer to effectively prevent impurity ions from diffusing, prevent moisture or external air from penetrating, and flatten a surface. The buffer layer 101 may include silicon oxide, silicon nitride, or silicon oxynitride. The buffer layer 101 may control a rate of providing heat during a crystallization process to form a semiconductor layer 110, and thus the semiconductor layer 110 may be uniformly crystallized.

The semiconductor layer 110 may be disposed on the buffer layer 101. The semiconductor layer 110 may include polysilicon and include a channel area that is not doped with impurities, and a source area and a drain area that are formed by doping impurities on both sides of the channel area. Here, the impurities vary depending on the type of thin film transistor, and may be N-type impurities or P-type impurities. Although not shown in the drawing, the display device according to an embodiment of the disclosure may further include another semiconductor layer disposed on another layer.

A gate insulating film 102 may be disposed on the semiconductor layer 110. The gate insulating film 102 may be a component to ensure insulation between the semiconductor layer 110 and a gate layer 120. The gate insulating film 102 may include an inorganic material such as silicon oxide, silicon nitride, and/or silicon oxynitride and may be located between the semiconductor layer 110 and the gate layer 120. The gate insulating film 102 may be formed to correspond to an entire surface of the substrate 100 and may have a structure in which contact holes are formed in preset portions. As such, an insulating film including an inorganic material may be formed through chemical vapor deposition (CVD) or atomic layer deposition (ALD). This is also applied to the embodiments and modifications thereof described below.

The gate layer 120 may be disposed on the gate insulating film 102. The gate layer 120 may be located at a position that overlaps the semiconductor layer 110 vertically, and may include at least one metal selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu). Detailed features of the gate layer 120 will be described below. Although not shown in the drawing, the display device according to the disclosure may further include another gate layer disposed on another layer.

An interlayer insulating film 103 may be disposed on the gate layer 120. The interlayer insulating film 103 may cover the gate layer 120. The interlayer insulating film 103 may include an inorganic material. In an embodiment, for example, the interlayer insulating film 103 may include metal oxide or metal nitride, e.g.,, the inorganic material may include silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO₂). In some embodiments, the interlayer insulating film 103 may have a dual structure of SiOx/SiNy or SiNx/SiOy.

A conductive layer 130 may be disposed on the interlayer insulating film 103. The conductive layer 130 may function as an electrode connected to the source/drain areas of the semiconductor layer through a through hole provided in the interlayer insulating film 103.

The conductive layer 130 may include at least one metal selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In an embodiment, for example, the conductive layer 130 may include a Ti layer, an Al layer, and/or a Cu layer. In an embodiment, for example, the conductive layer 130 may have a Ti/Al/Ti structure.

Although not shown in the drawing, the display device according to an embodiment of the disclosure may further include another conductive layer disposed on another layer, and the other conductive layer may be, for example, a wiring layer that functions as a wiring. The other conductive layer may include a same material as the conductive layer 130 and may have a same layer structure as the conductive layer 130.

An organic insulating layer 104 may be disposed on the conductive layer 130. The organic insulating layer 104 may have a generally flat upper surface that covers an upper portion of the conductive layer 130 and may be an organic insulating layer that functions as a planarization film. The organic insulating layer 104 may include an organic material such as acrylic, benzocyclobutene (BCB), or hexamethyldisiloxane (HMDSO). The organic insulating layer 104 may be modified in various ways, and for example, may be defined by a single layer or multiple layers.

Although not shown in the drawing, the display device according to the disclosure may further include another organic insulating layer disposed on another layer. Another organic insulating layer may be disposed on the other conductive layer described above, and may cover an upper portion of the other conductive layer to function as a planarization film. The other organic insulating layer may include a same material as the organic insulating layer 104 and may have a same layer structure as the organic insulating layer 104.

A pixel electrode 140 may be disposed on the organic insulating layer 104. Alternatively, the pixel electrode 140 may be disposed on the other organic insulating layer described above. However, for convenience of description, it is assumed that the pixel electrode 140 is disposed on the organic insulating layer 104.

The pixel electrode 140 may be connected to the conductive layer 130 through a contact hole formed in the organic insulating layer 104. A display element may be disposed on the pixel electrode 140. An organic light emitting device OLED may be used as a display device. That is, the organic light emitting device OLED may be located on the pixel electrode 140, for example. The pixel electrode 140 may include a transmissive conductive layer including a transmissive conductive oxide such as ITO, In₂O₃, or IZO, and/or a reflective layer including a metal such as Al or Ag. In an embodiment, for example, the pixel electrode 140 may have a three-layer structure of ITO/Ag/ITO.

A pixel defining film 105 may be located on the organic insulating layer 104 and may be located to cover an edge of the pixel electrode 140. In an embodiment, for example, the pixel defining film 105 may cover the edge of the pixel electrode 140. The pixel defining film 105 may be provided with an opening corresponding to a pixel, and the opening may be formed to expose at least a central portion of the pixel electrode 140 therethrough. The opening may be defined by the pixel defining film 105.

The pixel defining film 105 may include an organic material such as polyimide or hexamethyldisiloxane (HMDSO). A spacer 80 may be disposed on the pixel defining film 105. The spacer 80 is shown located in the peripheral area PA, but may also be located in the display area DA. The spacer 80 may effectively prevent the organic light emitting device OLED from being damaged by sagging of a mask during a manufacturing process using the mask. The spacer 80 may include an organic cleavage and may include a single layer or multiple layers.

An intermediate layer 150 and a counter electrode 160 may be disposed on the above-described opening. The intermediate layer 150 may include a low-molecular or high-molecular material. In an embodiment where the intermediate layer 150 includes a low-molecular material, the intermediate layer 150 may include a hole injection layer, a hole transport layer, an emission layer, an electron transport layer, and/or an electron Injection Layer. In an embodiment where the intermediate layer 150 includes a high-molecular material, the intermediate layer 150 may generally have a structure including a hole transport layer (HTL) and an emission layer (EML).

The structure of the intermediate layer 150 is not limited to those described above, and may have various structures. In an embodiment, for example, at least one of the layers forming the intermediate layer 150 may be formed integrally with the counter electrode 160. According to another embodiment, the intermediate layer 150 may have a layer patterned to correspond to each of the plurality of pixel electrodes 140.

The counter electrode 160 may include a transmissive conductive layer including a transmissive conductive oxide such as ITO, In₂O₃, or IZO. The pixel electrode 140 may be used as an anode, and the counter electrode 160 may be used as a cathode, or vice versa.

The counter electrode 160 may be disposed on an upper portion of the display area DA and may be disposed on an entire surface of the display area DA. That is, the counter electrode 160 may be formed as one body to cover a plurality of pixels. The counter electrode 160 may be in electrical contact with a common power supply line 70 located in the peripheral area PA. In an embodiment, for example, the counter electrode 160 may extend to a partition wall 200.

A thin film encapsulation layer TFE may cover the entire display area DA and may extend toward the peripheral area PA to cover at least a portion of the peripheral area PA. The thin film encapsulation layer TFE may extend to the outside of the common power supply line 70.

The thin film encapsulation layer TFE may include a first inorganic encapsulation layer 310, a second inorganic encapsulation layer 330, and an organic encapsulation layer 320 located therebetween. The first inorganic encapsulation layer 310 and the second inorganic encapsulation layer 330 may include one or more inorganic materials such as aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may include a single layer or multiple layers including the above-described material. The first inorganic encapsulation layer 310 and the second inorganic encapsulation layer 330 may include a same material as each other or different materials from each other.

The thicknesses of the first inorganic encapsulation layer 310 and the second inorganic encapsulation layer 330 may be different from each other. The thickness of the first inorganic encapsulation layer 310 may be greater than the thickness of the second inorganic encapsulation layer 330. Alternatively, the thickness of the second inorganic encapsulation layer 330 may be greater than the thickness of the first inorganic encapsulation layer 310, or the thicknesses of the first inorganic encapsulation layer 310 and the second inorganic encapsulation layer 330 may be the same.

The organic encapsulation layer 320 may include a monomer-based material or a polymer-based material. The polymer-based material may include acrylic resin, epoxy resin, polyimide, and polyethylene. In an embodiment, for example, the organic encapsulation layer 320 may include acrylate.

The partition wall 200 may be located in the peripheral area PA of the substrate 100. In an embodiment, for example, the partition wall 200 may include a portion 230 of the organic insulating layer 104, a portion 220 of the pixel defining film 105, and a portion 210 of the spacer 80, but is not necessarily limited thereto. In some cases, the partition wall 200 may include at least one of the portion 230 of the organic insulating layer 104, the portion 220 of the pixel defining film 105, and the portion 210 of the spacer 80.

The partition wall 200 may be located to surround the display area DA, and may prevent the organic encapsulation layer 320 of the thin film encapsulation layer TFE from overflowing to the outside of the substrate 100. Accordingly, the organic encapsulation layer 320 may be in contact with an inner lateral surface of the partition wall 200 facing the display area DA. In this case, when the organic encapsulation layer 320 is in contact with the inner lateral surface of the partition wall 200, it may be understood that the first inorganic encapsulation layer 310 is located between the organic encapsulation layer 320 and the partition wall 200 and that the organic encapsulation layer 320 is in contact with the first inorganic encapsulation layer 310. The first inorganic encapsulation layer 310 and the second inorganic encapsulation layer 330 are disposed on the partition wall 200 and may extend toward the edge of the substrate 100.

According to another embodiment, the thin film encapsulation layer TFE may be replaced with a cover member that covers the entire display area DA. The cover member may be located to cover not only the display area DA but also at least a portion of the peripheral area PA. The cover member may include a rigid member (e.g., glass). When the thin film encapsulation layer TFE is replaced by a cover member, the partition wall 200 described above may be omitted. In some cases, a transparent filler may be located between the cover member and the counter electrode 160.

According to embodiments of the disclosure, as described above, a display device and a manufacturing method thereof for preventing damage due to pressure applied when a certain component is attached to a display panel may be implemented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel including one surface, on which a screen is defined, and an opposing surface located opposite to the one surface;
a first bonding target located in a first area of the opposing surface; and
a first resin layer located between the first bonding target and the opposing surface and covering at least a portion of a lateral surface of the first bonding target.

2. The display device of claim 1, further comprising a first upper resin layer disposed on the first resin layer and covering at least a portion of an upper surface of the first bonding target.

3. The display device of claim 1, wherein, when viewed in a direction perpendicular to the opposing surface, an area of the first resin layer is greater than an area of the first bonding target.

4. The display device of claim 1, further comprising a cushion layer located between the first resin layer and the opposing surface.

5. The display device of claim 1, wherein the first resin layer includes one of an optical curing resin and a thermo-curing resin.

6. The display device of claim 5, wherein the first resin layer further includes a metallic material mixed with the one of the optical curing resin and the thermo-curing resin.

7. The display device of claim 1, further comprising:
a second bonding target located in a second area of the opposing surface, which is located around the first area; and
a second resin layer located between the second bonding target and the opposing surface and covering at least a portion of a lateral surface of the second bonding target.

8. The display device of claim 7, wherein the first resin layer in the first area includes one of an optical curing resin and a thermo-curing resin, and
the second resin layer in the second area includes the other of the optical curing resin and the thermo-curing resin.

9. The display device of claim 1, further comprising an integrated circuit film which is connected to the display panel and on which a driving integrated circuit is mounted,
wherein the first bonding target includes a printed circuit board connected to the integrated circuit film.

10. The display device of claim 1, wherein the first resin layer covers at least a portion of an upper surface of the first bonding target.

11. A method of manufacturing a display device, the method comprising:
preparing a display panel including one surface, in which a screen is defined, and an opposing surface located opposite to the one surface;
forming a first resin layer on the opposing surface by applying a resin to a first area of the opposing surface;
locating a first bonding target on the first resin layer;
after the locating the first bonding target, waiting for a certain time; and
curing the first resin layer.

12. The method of claim 11, further comprising:
after the curing the first resin layer, forming a first upper resin layer by further applying the resin to the first resin layer and the first bonding target; and
curing the first upper resin layer.

13. The method of claim 11, further comprising forming a cushion layer on the opposing surface,
wherein the forming the first resin layer includes applying the resin to the opposing surface and the cushion layer.

14. The method of claim 11, wherein, when viewed in a direction perpendicular to the opposing surface, an area of the first resin layer is greater than an area of the first bonding target.

15. The method of claim 11, wherein the first resin layer includes an optical curing resin or a thermo-curing resin.

16. The method of claim 15, wherein the first resin layer further includes a metallic material mixed with the optical curing resin or the thermo-curing resin.

17. The method of claim 11, further comprising:
forming a second resin layer by applying the resin to a second area of the opposing surface, which is located around the first area; and
locating a second bonding target on the second resin layer.

18. The method of claim 17, further comprising:
after the locating the second bonding target, waiting for a certain time; and
curing the second upper resin layer.

19. The method of claim 18, wherein the first resin layer in the first area includes one of an optical curing resin and a thermo-curing resin, and
the second resin layer in the second area includes the other of the optical curing resin and the thermo-curing resin.

20. The method of claim 13, wherein, when viewed in a direction perpendicular to the opposing surface of the display panel, an area of the first resin layer is less than an area of the cushion layer.
